(19) United States
(12) Patent Application Publication
(10) Pub. No.: US 2009/0109515 A1
(43) Pub. Date: Apr. 30, 2009

(54) ENCAPSULATED SPATIAL LIGHT MODULATOR HAVING LARGE ACTIVE AREA

(75) Inventor: Shaoher X. Pan, San Jose, CA (US)

Correspondence Address: FISH & RICHARDSON P.C., PO BOX 1022, MINNEAPOLIS, MN, 55440-1022, US

(73) Assignee: SPATIAL PHOTONICS, INC., Sunnyvale, CA (US)

(21) Appl. No.: 11/929,809

(22) Filed: Oct. 30, 2007

(51) Int. Cl. G02B 26/00; H01L 23/00

(52) U.S. Cl. 359/290; 438/26; 257/E23.002

(57) ABSTRACT

A die for spatial light modulation includes a substrate having a top surface having a length less than 15 mm and a width less than 11 mm, a spacer wall on the top surface of the substrate, a transparent encapsulation cover on the spacer wall, wherein the spacer wall and the encapsulation cover define a cavity over the substrate, a spatial light modulator on the substrate and within the cavity, and an opaque aperture layer on a surface of the encapsulation cover. The aperture layer includes an opening exposing the transparent window to allow the spatial light modulator to receive a light beam from outside of the cavity or send a light beam outside of the cavity. The spacer wall has a thickness equal to or less than 0.5 millimeters.

### BACKGROUND

The present disclosure relates to the packaging of spatial light modulators.

In manufacturing spatial light modulators, spatial light modulators are commonly fabricated on a semiconductor wafer, sealed in micro chambers, and subsequently separated into individual dies or micro chambers. The micro chambers include transparent windows through which the spatial light modulators can receive and transmit optical signals. The dimensions of the transparent windows are typically comparable to the lateral dimensions of the spatial light modulator encapsulated in the micro chamber.

Spatial light modulators are typically used in display devices. To support miniaturization of these devices, the dies for the spatial light modulators are preferably made small. Moreover, to ensure optical performance of the spatial light modulators, it is important to prevent unwanted scattered light in the micro chambers from exiting the transparent window.

### SUMMARY

In one general aspect, the present invention relates to a die for spatial light modulation includes a substrate having a top surface having a length less than 15 mm and a width less than 11 mm, a spacer wall on the top surface of the substrate, a transparent encapsulation cover on the spacer wall, wherein the spacer wall and the encapsulation cover define a cavity over the substrate, a spatial light modulator on the substrate and within the cavity, and an opaque aperture layer on a surface of the encapsulation cover. The aperture layer includes an opening exposing the transparent window to allow the spatial light modulator to receive a light beam from outside of the cavity or send a light beam outside of the cavity. The spacer wall has a thickness equal to or less than 0.5 millimeters.

In another general aspect, the present invention relates to a die for spatial light modulation that includes a substrate having a top surface having a length less than 15 mm and a width less than 11 mm; a spacer wall on the top surface of the substrate; a transparent encapsulation cover on the spacer wall, wherein the spacer wall and the encapsulation cover define a cavity over the substrate; a spatial light modulator on the substrate and within the cavity; and an opaque aperture layer on a surface of the encapsulation cover. The aperture layer comprises an opening exposing the transparent window to allow the spatial light modulator to receive a light beam from outside of the cavity or send a light beam outside of the cavity. The opening in the aperture layer has a surface area equal to at least 60% of a surface area of the top surface of the substrate.

In another general aspect, the present invention relates to a method for encapsulating a spatial light modulator that includes forming an opaque aperture layer having a plurality of openings on a transparent encapsulation cover; forming spacer walls having a thickness equal to or less than 0.5 millimeters on a surface of the encapsulation cover; connecting the spacer walls to a surface of a substrate having a plurality of spatial light modulators to form a plurality of cavities on the substrate with each cavity encapsulating at least one spatial light modulator, wherein the aperture layer in the cavity includes an opening that allows the spatial light modulator to receive a light beam from outside of the cavity or send a light beam outside of the cavity; and cutting the substrate and the encapsulation cover to form a plurality of dies each including a spatial light modulator in a cavity. The substrate in each die includes a top surface having a length less than 15 mm and a width less than 11 mm and the opening in the aperture layer in the cavity in the die has an area equal to at least 60% of the top surface of the die.

Implementations of the system may include one or more of the following features. The aperture layer is on a lower surface of the encapsulation cover and at least a portion of the aperture layer is inside the cavity. The die can further include an electrode configured to send electric signals to or receive electric signals from the spatial light modulator, wherein the electrode is on a portion of the top surface of the substrate that is outside the cavity. The spacer wall can define a cavity height between the substrate and the encapsulation cover, wherein the cavity height is between about 0.1 millimeters and about 1.0 millimeters. A distance between the top surface of the substrate and a top surface of the encapsulation cover can be between about 0.2 millimeters and about 2.0 millimeters. A distance between a top surface of the encapsulation cover and a bottom surface of the substrate can be 4 millimeters or less. The die can further include an anti-reflective layer formed on a surface of the encapsulation cover. At least a portion of the anti-reflective layer can be between the lower surface of the encapsulation cover and the aperture layer. The top surface of the substrate can have a length less than 15 mm and a width less than 11 mm, wherein the substrate in each die includes a top surface and the opening in the aperture layer in the cavity in the die has an area equal to at least 60% of the top surface of the die. The die can further include a light absorbing material on a surface defining the cavity, the light absorbing material configured to absorb light in the cavity. The light absorbing material can be on at least one of a surface of the spacer wall, a lower surface of an aperture layer on a lower surface of the encapsulation cover, or a top surface of the substrate in the cavity. The die can further include a moisture absorbing material on a surface defining the cavity. The aperture layer can be on a lower surface of the encapsulation cover and the moisture absorbing material is on a surface of the aperture layer inside the cavity. The spatial light modulator can include an array of tiltable mirrors and the array is characterized by a first lateral dimension and a second lateral dimension, wherein the first lateral dimension of the array of tiltable mirrors is wider than a corresponding dimension of the opening in the aperture layer. The spatial light modulator can include a tiltable mirror configured to tilt to an on position to reflect an incident light through the opening and to tilt to an off position where reflected incident light is not directed through the opening.

Various implementations of the methods and devices described herein may include one or more of the following advantages. The disclosed encapsulated spatial light modulators can have compact sizes to support device miniaturization. In the micro chamber for the disclosed encapsulated spatial light modulator, the window for transmitting optical signals to and from the spatial light modulator encapsulated in a chamber represents a larger fraction of the die area compared to some conventional systems. The inactive areas on the die not for optical transmissions are reduced compared to some conventional systems. A combination of materials and the manufacturing methods used with the materials to form the spacer walls allows the spacer walls to be thin and at the same provide hermetic sealing. Because the materials are amorphous, their surfaces can be fabricated into a smooth surface, which is easier to bond to a wafer. Smoother surfaces can lead to better hermetic sealing. The smaller, hermetically sealed chambers can be used in smaller devices, such as portable devices.

Additionally, unwanted light may be absorbed in a micro chamber that encapsulates the spatial light modulator. The optical noise in the output optical signal can therefore be reduced. The image contrast of a display image formed by the disclosed spatial light modulator can thus be increased. The contrast between an “on” state and an “off” state of the spatial light modulator may also be increased. Increasing contrast can improve image quality. The specification also discloses manufacturing processes for encapsulation devices that include light absorbing components that can absorb the unwanted light in the chambers.

Furthermore, moisture in a micro chamber that encapsulates the spatial light modulator can be absorbed by a moisture absorbing material disposed in the micro chamber. The reduced moisture content in the micro chamber can improve the performance of the encapsulated spatial light modulator.

Although the invention has been particularly shown and described with reference to multiple embodiments, it will be understood by persons skilled in the relevant art that various changes in form and details can be made therein without departing from the spirit and scope of the invention.

### BRIEF DESCRIPTION OF THE DRAWINGS

The following drawings, which are incorporated in and form a part of the specification, illustrate embodiments of the present invention and, together with the description, serve to explain the principles, devices and methods described herein.

FIG. 1A is a schematic cross-sectional view of a spatial light modulator encapsulated in a chamber.

FIG. 1B is a schematic top view of the spatial light modulator encapsulated in the chamber shown in FIG. 1A.

FIG. 2A is a schematic of an enlarged top view of the spatial light modulator including an array of pixel cells each including a micro mirror.

FIG. 2B is a cross-sectional view of an exemplary micro mirror in the spatial light modulator of FIG. 2A.

FIGS. 3A and 3B illustrate directions of incident light and reflected light when a micro mirror plate in a pixel cell of a spatial light modulator is tilted to an “on” and an “off” direction, respectively.

FIG. 4 is a schematic diagram showing incident light and reflected light in the chamber when a micro mirror plate in a pixel cell of a spatial light modulator is tilted to an “off” direction.

FIG. 5 is a flowchart showing the steps of fabricating an encapsulation device and encapsulating a spatial light modulator on a substrate using the encapsulation device.

FIG. 6 is a top view of an encapsulation cover assembly.

FIGS. 7A-7J are cross-sectional views along A-A in FIG. 6, showing the steps of fabricating an encapsulation device and encapsulating a spatial light modulator on a substrate using the encapsulation device.

### DETAILED DESCRIPTION

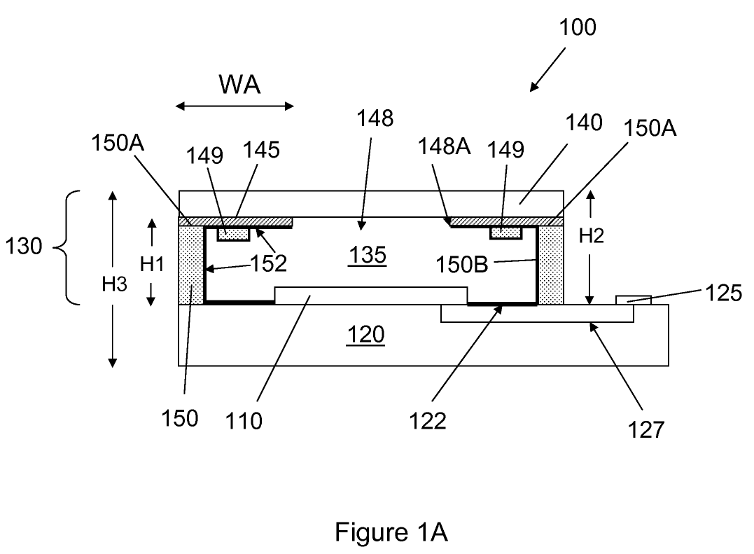

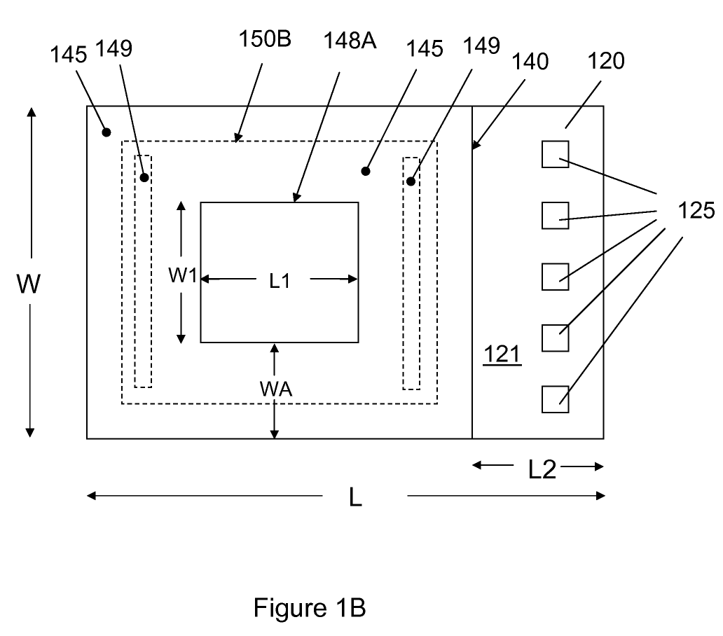

Referring to FIGS. 1A and 1B, a die 100 includes a spatial light modulator 110 formed or mounted onto a substrate 120. The spatial light modulator 110 can be mounted on the substrate 120 by wire bonding or flip-chip bonding. The substrate 120 can include an electric circuit 127 that electrically connects the spatial light modulator 110 to electric contacts 125 in an area 121 on the substrate 120 outside of a chamber 135. The electric contacts 125 allow the spatial light modulator 110 to receive external electric signals or to output electric signals. The electric circuits 127 can, for example, include conductor-metal-oxide semiconductor (CMOS) transistors.

The spatial light modulator 110 is encapsulated by an encapsulation device 130, which in part defines the chamber 135. The encapsulation device 130 can include an encapsulation cover 140 that can be made of a material that is transparent to visible, UV, or IR light. The thickness of the cover 140 can be in the range of about 0.2 mm to 1.2 mm, such as 0.5 mm to 1.0 mm or about 0.7 mm. An opaque aperture layer 145 can be formed on the lower surface of an encapsulation cover 140. The aperture layer 145 can be made of an opaque material, such as chromium oxide. The lower surface of the aperture layer 145 can be coated with a layer 152 of a light absorbing material. In some embodiments, the light absorbing material absorbs light more efficiently than the aperture layer 145. An aperture (or opening) 148 in the opaque aperture layer 145 above the spatial light modulator 110 exposes the transparent encapsulation cover 140. The aperture 148 allows optical communications between the spatial light modulator 110 and a component or system outside of the chamber 135. One or more patches of moisture absorbing materials 149 (dashed lines show the absorbing material in phantom in FIG. 1B) are formed in the chamber 135, such as on the lower surface of the layer 152 of the light absorbing material.

The encapsulation device 130 can also include spacer walls 150 that are connected to the aperture layer 145 of the encapsulation cover 140 and to the substrate 120. The spacer walls 150 include internal surfaces 150B (dashed lines show the internal surfaces in phantom in FIG. 1B) facing the spatial light modulator 110. For example, the spacer walls 150 can be sealed to the substrate 120 by a polymer adhesive or bonded to the substrate 120 by plasma in the bonding areas 150A (the contact areas between the spacer walls 150 and the encapsulation cover 140 or the substrate 120). The spacer walls 150 can be made of an inorganic material, such as glass or a metal that is used in electroplating, such as chromium, silver, nickel, gold or copper. The encapsulation cover 140 can optionally include anti-reflective coatings on the upper or the lower surfaces.

The surfaces of the spacer walls 150 inside the chamber 135 are also coated with a layer 152 of a light absorbing material. Optionally, an outside surface of the spacer walls 150 can also be coated by a layer of light absorbing material. The upper surfaces of the substrate 120 that are outside of the spatial light modulator 110 and inside the chamber 135 are also disposed with a layer 122 of a light absorbing material. The light absorbing materials on of layer 122, layer 152, and aperture layer 145 can include for example a zirconium compound such as zirconium oxide and zirconium nitride.

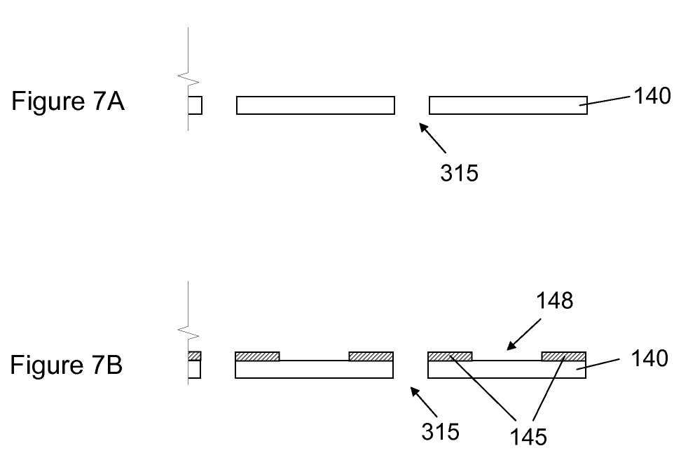

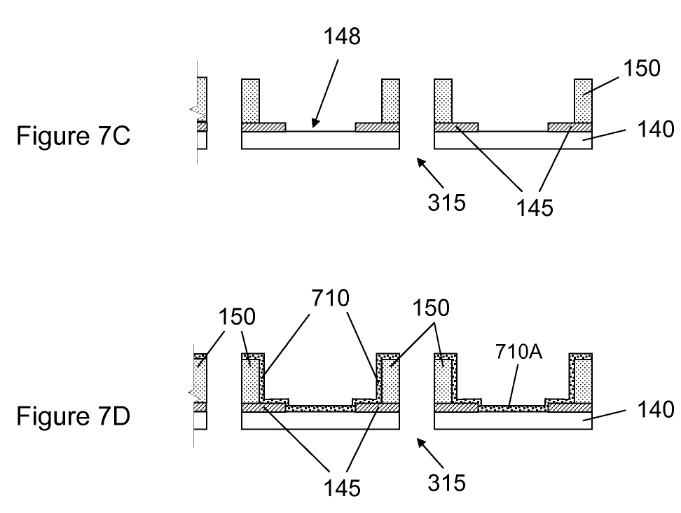

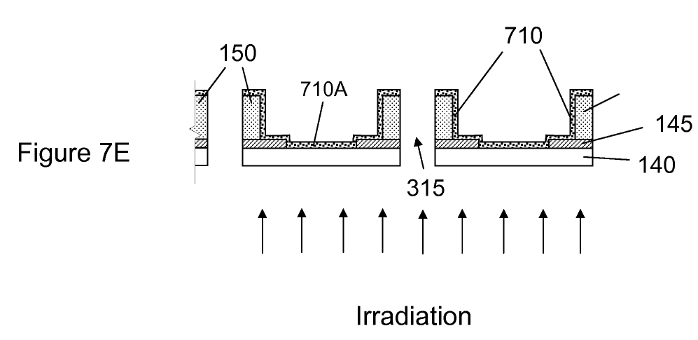

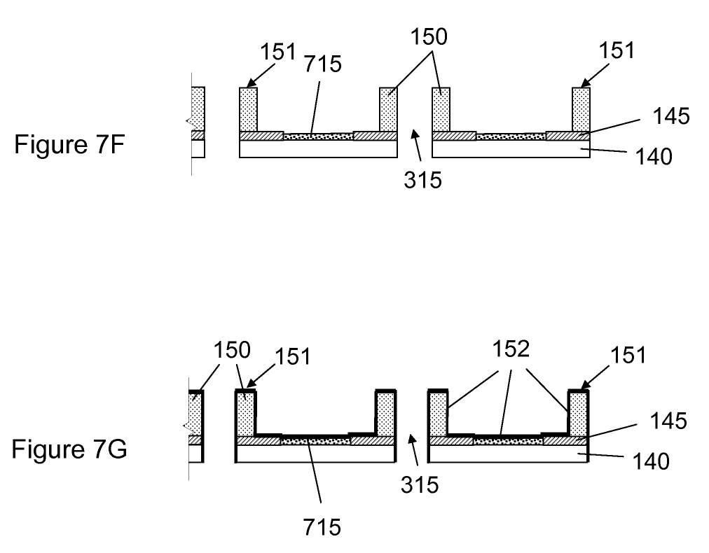

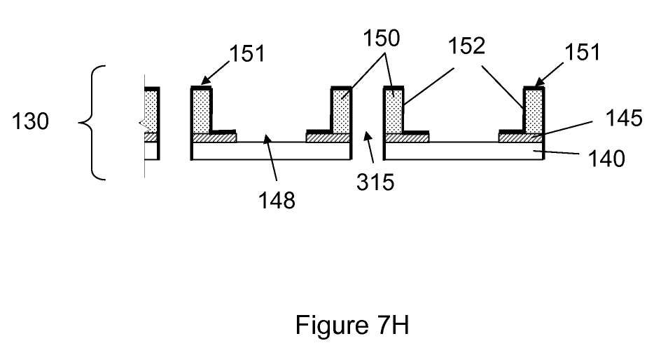

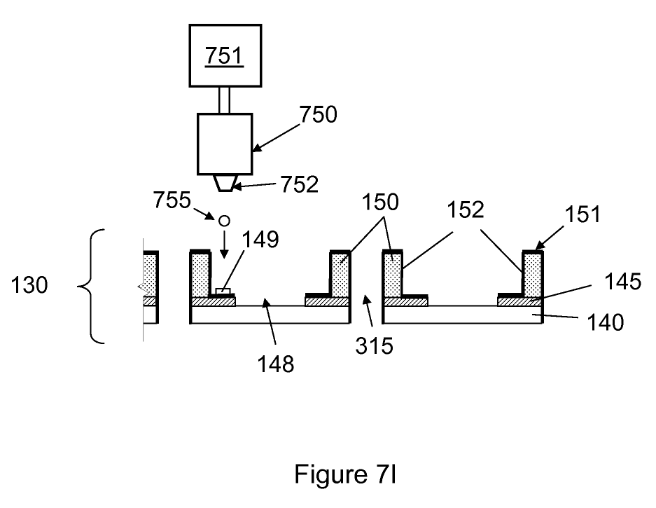

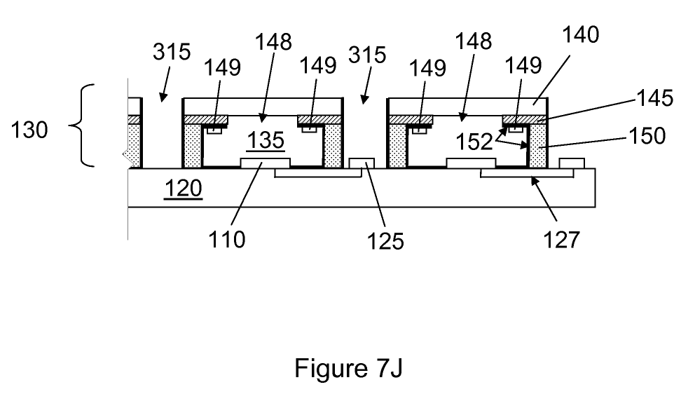

The aperture 148 is defined by aperture boundary 148A. The aperture boundary 148A can be a rectangle having a length L1 and a width W1. The opening of the aperture 148 thus has an area of L1×W1. The die 100 has also typically a rectangular shape. The top surface of the die 100 can be defined by a length L and a width W. The area of the top surface of the die 100 is thus L×W. In some embodiments, the die 100 have small lateral dimensions to enable device miniaturization. For example, the length L of the die area can be made less than 15 mm. The width W of the die area can be made less than II mm. In another example, the length L of the die area can be made less than 14 mm. The width W of the die area can be made less than 10 mm. In the disclosed system, the ratio of the area of the aperture 148 to the area of the top surface of the die 100, (L1×W1)/(L×W), is higher than 60%, or higher than 70%. (Note that FIGS. 1A-1B, and FIGS. 7A-7J are not to scale for illustrating all the components in the micro chamber. The actual aperture covers a larger fraction of the die area than in these Figures.) In comparison, some conventional systems have an aperture that covers less than 50% of the area of the top surface of their dies.

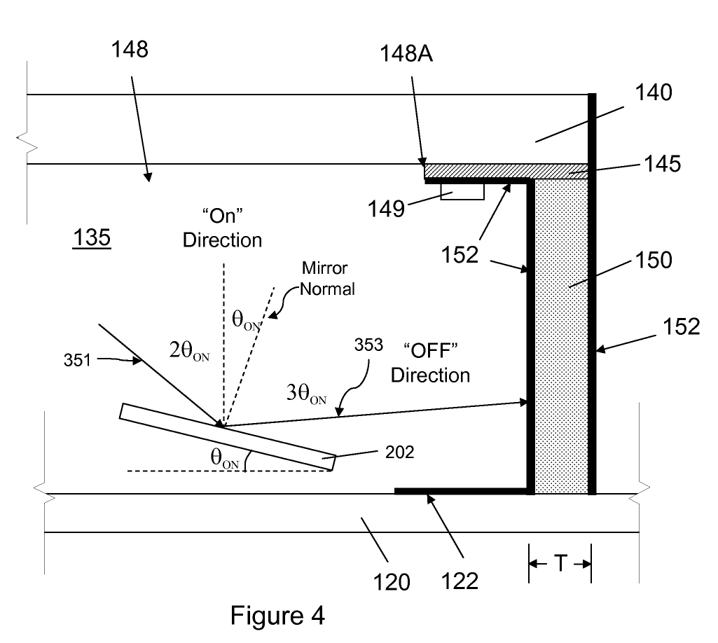

Specifically, when both the die 100 and the opening 148 have rectangular shapes, the area ratio can be expressed by (W1×L1)/WL. The relatively high area ratio is achieved by reducing the areas on the die 100 that do not contribute to light transmission. For example, the spacer wall 150 can be constructed to have a thickness T (shown in FIG. 4) smaller than about 1 millimeters, or 0.5 millimeters, while still providing a hermetic sealing to the spatial light modulator 110 in the chamber 135. The hermetic sealing is achieved by a thinner spacer wall 150 when the bond at the interface between the substrate 120 and the bottom faces of the spacer wall 150 is improved. Specifically, the strength of the bond can be improved by forming smoother surfaces at the bottom faces of the spacer wall 150 (see step 585 and the description in relation to FIG. 7G-7J below). Smoother surfaces at the bottom faces of the spacer wall 150 can enable stronger bonding and thus tighter sealing of the chamber 135, which allows hermetic sealing to be achieved by thinner spacer wall 135.

When inorganic materials that are amorphous are used to form the spacer wall 135, the materials can be formed or processed to have a very smooth surface, in particular, the surface that contacts the wafer can be made very smooth. If the spacer wall is formed of glass, the surface can be polished. If the spacer wall is formed of metal, the wall can be formed with a slow deposition process, such as CVD or electroplating at a reduced rate, which forms a smooth surface.

In another example, the thickness T of the spacer wall 150 can be about 0.3 millimeters. The width L2 of the area 121 outside of the chamber 135 can be smaller than about 1 millimeter, or smaller than about 0.7 millimeter. The width WA of the opaque portion of aperture layer 148 can be in the range about 0.9 millimeter and about 1.5 millimeters.

The height of chamber 135, H1, is defined by the height of the spacer walls 140, which can be in a range from about 0.1 millimeter to about 1.0 millimeter. The distance H2 between the top surface of the encapsulation cover 140 and the top surface of the substrate 120 can be in a range from about 0.2 millimeter to about 2.0 millimeter. The thickness H3 of the die 100 is the distance between the top surface of the encapsulation cover 140 and the bottom surface of the substrate 120. H3 can be equal to or less than about 5 millimeters, or equal to or less than about 4 millimeters.

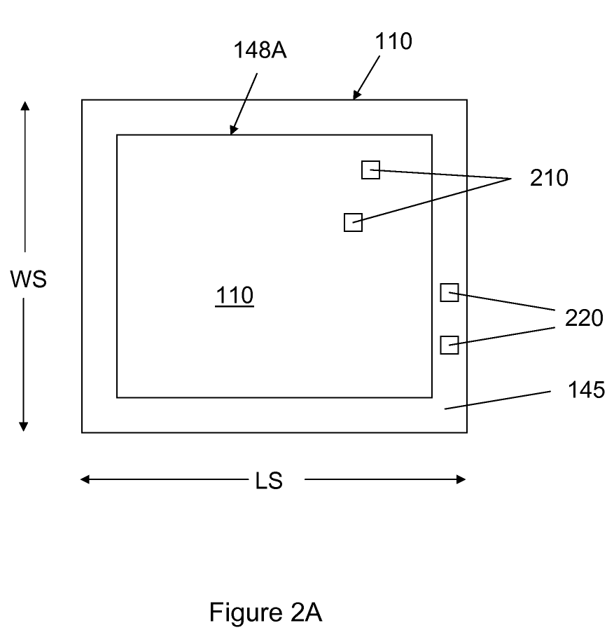

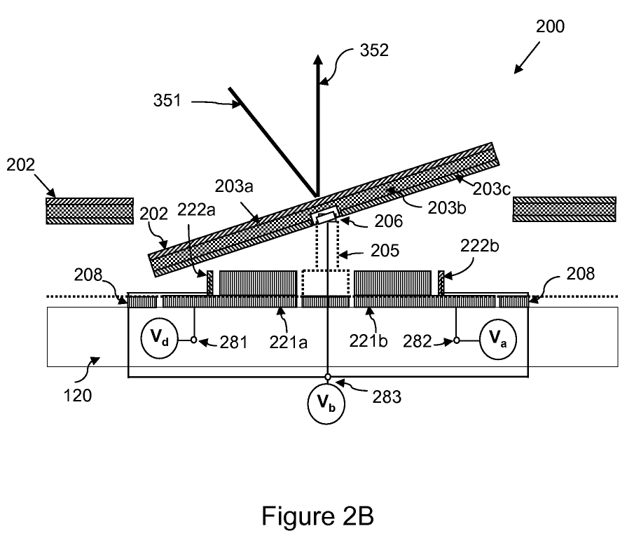

Referring to FIG. 2A, the spatial light modulator 110 can include a plurality of pixel cells 210, 220 that can be distributed in an array that is characterized by two lateral dimensions LS and WS (only a few pixel cells are shown for the sake of simplicity). Some pixel cells 210 are under the aperture 148 defined by the aperture boundary 148A. The pixel cells 210 are thus under the window defined by the aperture 148 and can easily receive or output optical signals from or to the outside of the chamber 135.

In some embodiments, some other pixel cells 220 in the spatial light modulator 110 are positioned under the aperture layer 145. The pixel cells 220 are not used for optical communications or light modulations during device operation. The pixel cells 220 can be referred as dummy pixel cells. One purpose for the dummy pixel cells is to overcome possible registration error between the aperture 148 and the spatial light modulator 110. When an encapsulation device 130 is bonded to the substrate 120, small alignment errors may occur in the relative lateral positions between the spatial light modulator 110 and the aperture 148. If the active area of the spatial light modulator 110 is made exactly the same size as that of the aperture 148, a small lateral misalignment between the spatial light modulator 110 and the aperture 148 can produce an inactive area inside the aperture 148, that is, certain areas under the aperture 148 may not include pixel cells for optical communications such as spatial light modulations. The array of the pixel cells 210, 220 in the spatial light modulator 110 is therefore made larger than the aperture 148 to ensure the pixel cells 210 fill the area within the aperture boundary 148 despite potential alignment errors. In other words, at least one of the lateral dimensions LS and WS of the array of pixel cells 210 and 220 is wider than the corresponding width of the opening 148.

Referring to FIG. 2B, a pixel cell 210 or 220 can include a tiltable micro mirror 200. The tiltable micro mirror 200 can include a mirror plate 202 that includes a flat reflective upper layer 203a, a middle layer 203b that provides the mechanical strength for the mirror plate, and a bottom layer 203c. The upper layer 203a can be formed of a reflective material such as aluminum, silver, or gold. The layer thickness of the upper layer 203a can be in the range of between about 200 and 1000 angstroms, such as about 600 angstroms. The middle layer 203b can be made of a silicon based material, for example, amorphous silicon, typically about 2000 to 5000 angstroms in thickness. The bottom layer 203c can be made of an electrically conductive material that allows the electric potential of the bottom layer 203c to be controlled relative to the step electrodes 221a or 221b. The bottom layer 203c can be made of titanium and have a thickness in the range of about 200 to 1000 angstroms.

A hinge 206 is connected with the bottom layer 203c (the connections are out of plane of view and are thus not shown in FIG. 2B). The hinge 206 is supported by a hinge post 205 that is rigidly connected to the substrate 120. The mirror plate 202 can include two hinges 206 connected to the bottom layer 203c. The two hinges 206 define an axis about which the mirror plate 202 can be tilted. The hinges 206 can extend into cavities in the lower portion of mirror plate 202. For ease of manufacturing, the hinge 206 can be fabricated as part of the bottom layer 203c.

Step electrodes 221a and 221b, landing tips 222a and 222b, and a support frame 208 can also be fabricated over the substrate 120. The heights of the step electrodes 221a and 221b can be in the range from between about 0.2 mm and 3 mm. The step electrode 221a is electrically connected to an electrode 281 whose voltage Vd can be externally controlled. Similarly, the step electrode 221b is electrically connected with an electrode 282 whose voltage Va can also be externally controlled. The electric potential of the bottom layer 203c of the mirror plate 202 can be controlled by an electrode 283 at potential Vb.

Bipolar electric pulses can individually be applied to the electrodes 281, 282, and 283. Electrostatic forces can be produced on the mirror plate 202 when electric potential differences are created between the bottom layer 203c on the mirror plate 202 and the step electrodes 221a or 221b. An imbalance between the electrostatic forces on the two sides of the mirror plate 202 causes the mirror plate 202 to tilt from one orientation to another.

The landing tips 222a and 222b can have a same height as that of a second step in the step electrodes 221a and 221b for manufacturing simplicity. The landing tips 222a and 222b provide a gentle mechanical stop for the mirror plate 202 after each tilt movement. The landing tips 222a and 222b can also stop the mirror plate 202 at a precise angle. Additionally, the landing tips 222a and 222b can store elastic strain energy when they are deformed by electrostatic forces and convert the elastic strain energy to kinetic energy to push away the mirror plate 202 when the electrostatic forces are removed. The push-back on the mirror plate 202 can help separate the mirror plate 202 and the landing tips 222a and 222b. Alternatively, the micro mirror 200 can be formed without landing tips 222a and 222b.

Details about the structures and operations of micro mirrors are disclosed for example in commonly assigned U.S. Pat. No. 7,167,298, titled “High contrast spatial light modulator and method” and U.S. patent application Ser. No. 11/564,040, entitled “Simplified manufacturing process for micro mirrors”, filed Nov. 28, 2006, the content of which are incorporated herein by reference.

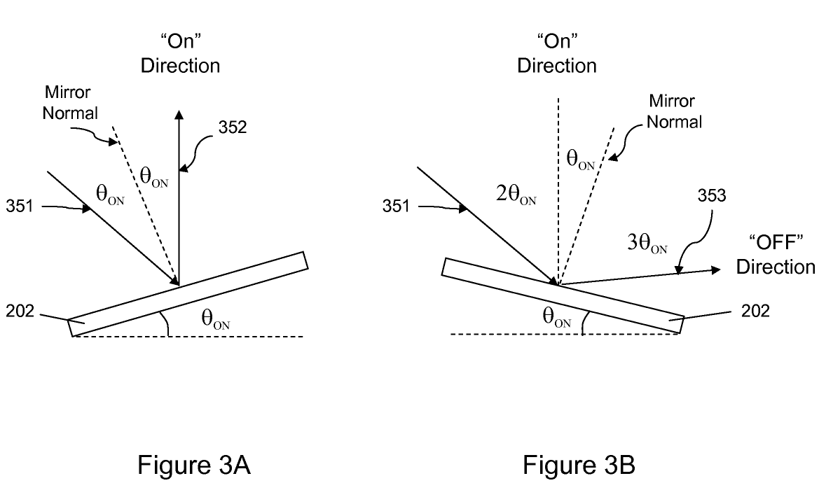

Referring to FIGS. 3A and 3B, the un-tilted position for the mirror plate 202 is typically the horizontal direction parallel to the upper surface of the substrate 120. The mirror plate 202 can be tilted by a tilt angle θₒₙ from the un-tilted position to an “on” position. The flat reflective upper layer of the mirror plate 202 can reflect the incident light 351 to produce the light 352 along the “on” direction. Since the incident angle (i.e., the angle between the incident light 330 and the mirror normal direction) and the reflection angle (i.e. the angle between the reflected light 340 and the mirror normal direction) are the same, the incident light 330 and the reflected light 340 form an angle 2θₒₙ that is twice as large as the tilt angle θₒₙ of the mirror plate 202. The “on” direction is typically configured to be perpendicular to the substrate 120.

The mirror plate 202 can be symmetrically tilted in an opposite direction to an “off” position. The mirror plate 202 can reflect the incident light 351 to form reflected light 353 traveling in the “off” direction. Because the incident angle for the incident light 330 is 3θₒₙ, the reflection angle should also be 3θₒₙ. Thus the angle between the light 352 and the light 353 is 4θₒₙ, four times as large as the tilt angle θₒₙ of the mirror plate 202. Typically, the tiltable micro mirror 200 is designed to produce the light 353 that travels substantially in the lateral direction.

Referring to FIG. 4, the light 353 reflected by the mirror plate 202 can travel in the “off” direction inside the chamber 135 (FIG. 4 illustrates only a single mirror plate for clarity; all of the mirror plates of the spatial light modulator would similarly be positioned in the chamber 135). The light 353 can impinge on the layer 152 of light absorbing material coated on the internal surfaces of the spacer walls 150 and be absorbed by the light absorbing material in the layer 152. Other unwanted light in the chamber 135 can include light scattered by the surfaces and objects in the chamber 135. The unwanted light can also be absorbed by the layer 122 on the surface of the substrate 120 and the aperture layer 145 on the lower surface of the encapsulation cover 140. When the mirror plate 202 is tilted to an “off” direction, it is desirable that no light can travel outside of the chamber 135 through the aperture 148. An important measure for the performance of the spatial light modulator 110 is the ratio of the output light intensities when the mirror plate is tilted to the “on” and the “off” directions. The effective absorption of light 353 and other unwanted light in the chamber 135 in the disclosed system can significantly reduce the unwanted light exiting the aperture 148 when the mirror pale is tilted to an “off” position. The contrast and the performance of the spatial light modulator 110 can thus be improved.

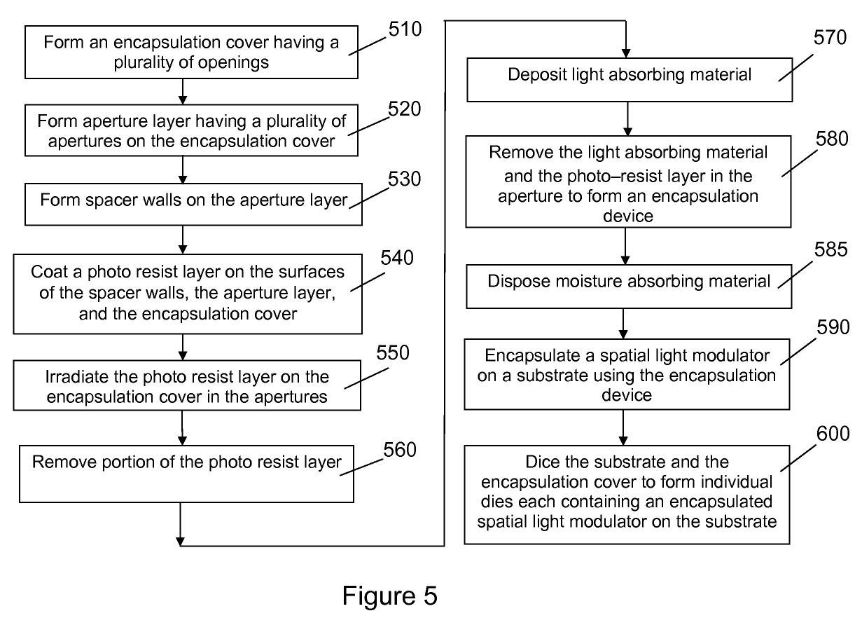

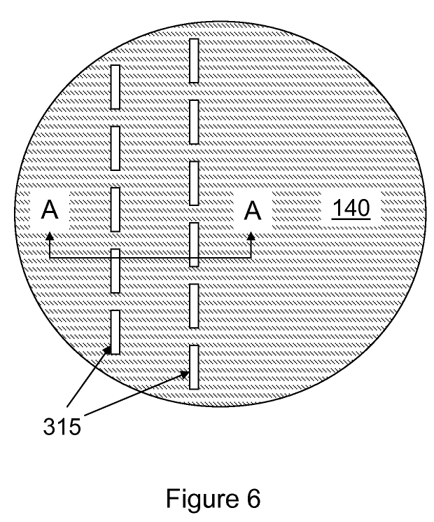

FIG. 5 is a flowchart showing the steps of fabricating an encapsulation device 130 and encapsulating a spatial light modulator 110 on a substrate 120 using the encapsulation device 130. Referring to FIGS. 6 and 7A, an encapsulation cover 140 having a plurality of openings 315 is formed (step 510). As described above, the encapsulation cover 140 is made of a transparent material. Each opening 315 is between chambers 135 to be defined by the intact portions of the cover 140. The openings 315 are provided for accessing the electric contacts 125 on the substrate 120 after the spatial light modulators 110 are encapsulated in chambers 135.

An opaque aperture layer 145 is next formed and patterned on a surface of the encapsulation cover 120 (FIG. 7B, step 520). The patterned aperture layer 145 defines a plurality of apertures 148 each associated with an opening 315 (and a chamber 135 to be formed). A plurality of spacer walls 150 are next formed on the patterned aperture layer 145 (FIG. 7C, step 530). The spacer walls 150 surround the apertures 148. Spacer walls 150 are also on at least one side of the opening 315, that is, at least a portion of the spacer wall is positioned adjacent to an opening 315. Examples of the materials for the spacer walls 150 can include a metal such as nickel, and copper. The spacer walls 150 can be formed by first forming a conductive layer on the encapsulation cover 120. A mask layer can then be formed on the conductive layer. The mask layer can have openings in the area where the spacer walls are to be built. The spacer walls are then formed in the openings by electrochemical plating. The spacer walls 150 can be formed by successive formation of a plurality of layers. Details about forming spacer walls using electrochemical plating are disclosed in commonly assigned pending U.S. patent application Ser. No. 11/680,600, entitled “Fabricating tall micro structure”, filed Feb. 28, 2007.

A negative photo resist is next spin-coated on the spacer walls 150 and the aperture layer 145, and the portion of the encapsulation cover 120 in the apertures 148 (FIG. 7D, step 540). A photo resist layer 710 is thereby formed on the surfaces of the spacer walls 150 and the aperture layer 145. A portion 710A of the photo resist layer is within the apertures 148. Photon irradiation is next applied from the side of the encapsulation cover 120 that is opposite to the photo resist layer 710 (FIG. 7E, step 550). Since the aperture layer 145 is opaque and the encapsulation cover 120 is transparent, only the portion 710A of the photo resist layer 710 in the aperture 148 is exposed to the photon irradiation. The photo resist layer 710A is subsequently cured by baking. The photo resist layer 710 is then removed by a developer while a cured photo resist layer 715 remains on the portion of the encapsulation cover 120 that is within the apertures 148 (FIG. 7F, step 560). Bottom faces 151 of the spacer walls 150 are also exposed.

A layer of light absorbing material is next deposited on the surfaces of the spacer walls 150 and the aperture layer 145, and the cured photo resist layer 715 (FIG. 7G, step 570). The light absorbing material can include a zirconium compound such as zirconium oxide and zirconium nitride. The light absorbing material can alternatively include amorphous carbon. The light absorbing material can be anisotropically deposited using chemical vapor deposition (CVD) on the aperture layer 145 and the bottom faces 151 of the spacer walls 150. The CVD can be controlled to assure the smoothness of the layer of light absorbing material 152 on the bottom faces 151 of the spacer walls 150. For example, the deposition rate in the CVD can be lowered to increase smoothness of the deposited materials. The encapsulation device 130 is finally formed by removing the cured photo resist layer 715 and the portion of the light absorbing material 152 on the cured photo resist layer 715 (FIG. 7H, step 580).

A moisture absorbing material is next disposed on the light absorbing material 152 on the aperture layer 145 (FIG. 7I, step 585). The moisture absorbing material can be delivered on the light absorbing material by a fluid dispensing device 750. The fluid dispensing device 750 is in fluid communication with a reservoir 751 that contains a fluid that includes the moisture absorbing material. The fluid dispensing device 750 includes a nozzle 752 that can eject the fluid to the surface of the light absorbing material 152. The solvent in the dispensed fluid containing the moisture absorbing material can evaporate, leaving solidified moisture absorbing material 149 on the surface of the light absorbing material 152. In some embodiments, the moisture absorbing material can also deposited on the light absorbing material 152 by physical vapor deposition. The deposition can be conducted in pre-defined areas using a mask.

The encapsulation device 130 can then be used to encapsulate a plurality of spatial light modulators 110 on substrate 120 (FIG. 7J, step 590). The surfaces of the spacer walls 150 are sealed to the upper surface of the substrate 120 with a polymer adhesive, such as epoxy or bonded to the upper surface of the substrate 120 by plasma bonding. The smoothness of the layer of light absorbing material 152 on the bottom faces 151 of the spacer walls 150 can improve the sealing or bonding of the encapsulation device 130 to the substrate 120, which allows hermetic sealing using thinner spacer walls of having thickness less than 1 mm or 0.5 mm. For example, decreased roughness at the bonding surface can increase the contact surface area between the spacer wall and the substrate in a plasma bonding, which can eliminate the probability of micro channels at the interface that connect the inside and outside of the chamber 135 to assure hermetic sealing. A seal can be achieved with a leakage rate of about 10-8 torr/min or less. A plurality of chambers 135 are thereby formed, each encapsulating one or more spatial light modulators 110. One or more electric contacts 125 are positioned on the substrate 120 in the opening 315 next to each chamber 135. The substrate 120 and the encapsulation cover 140 can then by diced to form individual dies each containing an encapsulated spatial light modulator 110 (step 600).

Other details about encapsulating spatial light modulators are disclosed in commonly assigned pending U.S. patent application Ser. No. 11/690,776, entitled “Encapsulated spatial light modulator having improved performance”, filed Mar. 23, 2007, this disclosure of which is incorporated herein by reference.

The above disclosed methods and devices may include one or more of the following advantages. The disclosed encapsulated spatial light modulators can have compact sizes to support device miniaturization. In the micro chamber for the disclosed encapsulated spatial light modulator, the window for transmitting optical signals to and from the spatial light modulator encapsulated in a chamber represents a larger fraction of the die area. The inactive areas on the die not for optical transmissions are reduced compared to some conventional systems. Additionally, unwanted light may be absorbed in a micro chamber that encapsulates the spatial light modulator. The optical noise in the output optical signal can therefore be reduced. The image contrast of a display image formed by the disclosed spatial light modulator can thus be increased. The contrast between an “on” state and an “off” state of the spatial light modulator may also be increased. The specification also discloses manufacturing processes for encapsulation devices that include light absorbing components that can absorb the unwanted light in the chambers. Furthermore, moisture in a micro chamber that encapsulates the spatial light modulator can be absorbed by a moisture absorbing material disposed in the micro chamber. The reduced moisture content in the micro chamber can improve the performance of the encapsulated spatial light modulator.

It is understood that the disclosed systems and methods are compatible with other light absorbing materials and other processes for introducing the light-absorbing materials in the chambers. The encapsulation cover and the spacer walls can be made of different materials and formed by different processes. The spacer walls can be connected to the encapsulation cover and the substrate by different sealing or bonding techniques. The spatial light modulators compatible with the disclosed system and methods can include many optical devices other than tiltable micro mirrors. The tiltable mirrors can be tilted to more positions than the disclosed on and off position. The tiltable mirrors may not include mechanical stops for stopping the tilt movement of the mirror plates. The positions of the tiltable mirrors may be defined by balances between electrostatic forces and elastic forces. The relative positions, form factors, dimensions, and shapes of the chambers, the spatial light modulators, and the electric contact can also vary without deviating from the present application.

What is claimed is:

1. A die for spatial light modulation, comprising:
a substrate having a top surface having a length less than 15 mm and a width less than 11 mm;
a spacer wall on the top surface of the substrate;
a transparent encapsulation cover on the spacer wall, wherein the spacer wall and the encapsulation cover define a cavity over the substrate;
a spatial light modulator on the substrate and within the cavity; and
an opaque aperture layer on a surface of the encapsulation cover, wherein the aperture layer comprises an opening exposing the transparent window to allow the spatial light modulator to receive a light beam from outside of the cavity or send a light beam outside of the cavity, wherein the spacer wall has a thickness equal to or less than 0.5 millimeters.

2. The die of claim 1, wherein the aperture layer is on a lower surface of the encapsulation cover and at least a portion of the aperture layer is inside the cavity.

3. The die of claim 1, further comprising an electrode configured to send electric signals to or receive electric signals from the spatial light modulator, wherein the electrode is on a portion of the top surface of the substrate that is outside the cavity.

4. The die of claim 1, wherein the spacer wall defines a cavity height between the substrate and the encapsulation cover, wherein the cavity height is between about 0.1 millimeters and about 1.0 millimeters.

5. The die of claim 1, wherein a distance between the top surface of the substrate and a top surface of the encapsulation cover is between about 0.2 millimeters and about 2.0 millimeters.

6. The die of claim 1, wherein a distance between a top surface of the encapsulation cover and a bottom surface of the substrate is 4 millimeters or less.

7. The die of claim 1, further comprising an anti-reflective layer formed on a surface of the encapsulation cover.

8. The die of claim 7, wherein at least a portion of the anti-reflective layer is between the lower surface of the encapsulation cover and the aperture layer.

9. The die of claim 1, wherein the top surface of the substrate has a length less than 15 mm and a width less than 11 mm, wherein the substrate in each die includes a top surface and the opening in the aperture layer in the cavity in the die has an area equal to at least 60% of the top surface of the die.

10. The die of claim 1, further comprising a light absorbing material on a surface defining the cavity, the light absorbing material configured to absorb light in the cavity.

11. The die of claim 10, wherein the light absorbing material is on at least one of a surface of the spacer wall, a lower surface of an aperture layer on a lower surface of the encapsulation cover, or a top surface of the substrate in the cavity.

12. The die of claim 1, further comprising a moisture absorbing material on a surface defining the cavity.

13. The die of claim 12, wherein the aperture layer is on a lower surface of the encapsulation cover and the moisture absorbing material is on a surface of the aperture layer inside the cavity.

14. The die of claim 1, wherein the spatial light modulator comprises an array of tiltable mirrors and the array is characterized by a first lateral dimension and a second lateral dimension, wherein the first lateral dimension of the array of tiltable mirrors is wider than a corresponding dimension of the opening in the aperture layer.

15. The die of claim 1, wherein the spatial light modulator comprises a tiltable mirror configured to tilt to an on position to reflect an incident light through the opening and to tilt to an off position where reflected incident light is not directed through the opening.

16. A die for spatial light modulation, comprising:
a substrate having a top surface having a length less than 15 mm and a width less than 11 mm;
a spacer wall on the top surface of the substrate;
a transparent encapsulation cover on the spacer wall, wherein the spacer wall and the encapsulation cover define a cavity over the substrate;
a spatial light modulator on the substrate and within the cavity; and
an opaque aperture layer on a surface of the encapsulation cover, wherein the aperture layer comprises an opening exposing the transparent window to allow the spatial light modulator to receive a light beam from outside of the cavity or send a light beam outside of the cavity, wherein the opening in the aperture layer has a surface area equal to at least 60% of a surface area of the top surface of the substrate.

17. A method for encapsulating a spatial light modulator, comprising:
forming an opaque aperture layer having a plurality of openings on a transparent encapsulation cover;
forming spacer walls having a thickness equal to or less than 0.5 millimeters on a surface of the encapsulation cover;
connecting the spacer walls to a surface of a substrate having a plurality of spatial light modulators to form a plurality of cavities on the substrate with each cavity encapsulating at least one spatial light modulator, wherein the aperture layer in the cavity includes an opening that allows the spatial light modulator to receive a light beam from outside of the cavity or send a light beam outside of the cavity; and
cutting the substrate and the encapsulation cover to form a plurality of dies each including a spatial light modulator in a cavity, wherein the substrate in each die includes a top surface having a length less than 15 mm and a width less than 11 mm and the opening in the aperture layer in the cavity in the die has an area equal to at least 60% of the top surface of the die.

18. The method of claim 17, wherein the spacer wall is formed on the aperture layer.

19. The method of claim 17, further comprising forming an electrode on a portion of the top surface of the substrate outside the cavity, wherein the electrode is configured to send electric signals to or receive electric signals from the spatial light modulator.

20. The method of claim 17, wherein the spacer wall defines a cavity height between the substrate and the encapsulation cover, wherein the cavity height is between about 0.1 millimeters and about 1.0 millimeters.

21. The method of claim 17, wherein a distance between the top surface of the substrate and a top surface of the encapsulation cover is between about 0.2 millimeters and about 2.0 millimeters.

22. The method of claim 17, wherein a distance between a top surface of the encapsulation cover and a bottom surface of the substrate is 4 millimeters or less.

23. The method of claim 17, further comprising:
forming an anti-reflective layer formed on a surface of the encapsulation cover;
disposing a light absorbing material on a surface to be enclosed in the cavity; and
disposing a moisture absorbing material on a surface to be enclosed in the cavity.

24. The method of claim 23, wherein the light absorbing material is formed on a portion of the aperture layer that is inside the cavity.

25. The method of claim 23, wherein the step of disposing a moisture absorbing material comprises:
dispensing a fluid comprising the moisture absorbing material on the surface to be enclosed in the cavity; and
removing a solvent from the fluid dispensed on the surface to be enclosed in the cavity.
